(19) United States
(12) Patent Application Publication
(10) Pub. No.: US 2004/0032284 A1
(43) Pub. Date: Feb. 19, 2004

(54) Digital electronic circuit for translating high voltage levels to low voltage levels

(75) Inventor: Manoj Kumar, New Delhi (IN)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics Pvt. Ltd., Uttar Pradesh (IN)

(21) Appl. No.: 10/460,044

(22) Filed: Jun. 12, 2003

(30) Foreign Application Priority Data
Jun. 13, 2002 (IN) 635/DEL/2002

(51) Int. Cl. H03K 19/0175

(52) U.S. Cl. 326/81

(57) ABSTRACT

A voltage level translator for digital logic circuits provides high level to low level voltage translation with equal rise and fall delays. The voltage level translator may include an input high voltage logic inverter (operating at the high voltage level) and connected to an output low voltage logic inverter operating at the low voltage level via a voltage reduction circuit. A related method for providing high level to low voltage translation may include providing an input inverter operating at the high voltage level and an output inverter operating at the low voltage level. Furthermore, the output of the high voltage inverter may be coupled to the input of the low voltage inverter after reducing the output voltage of the high voltage inverter to the required level.

### FIELD OF THE INVENTION

The present invention relates to the field of digital electronic circuits and, more particularly, to voltage level translators for translating high voltage levels to low voltage levels in digital integrated circuits.

### BACKGROUND OF THE INVENTION

Many modern digital electronic integrated circuits are designed with multiple sections. Some of these sections may operate at different operating voltages based on functional requirements, etc. These different sections interface with one another using voltage translators for providing signal level compatibility. Yet, the ever decreasing size of integrated circuit chips has necessitated a reduction in operating voltages to avoid latch-up and other operational problems such as electromagnetic interference (EMI), etc. As a result, the spacing between the conductors internal to the device have correspondingly decreased.

The use of lower operating voltages also reduces power consumption as well as the amount of heat generated from power dissipation, which can be particularly acute for relatively small device sizes. At the same time, functional requirements for interfacing with other devices typically require signal levels to be at significantly higher voltage levels, have minimum rise and fall times, and low average and peak power dissipation.

Referring to FIG. 1, a typical voltage translator 1 in accordance with the prior art for translating a high voltage input level to a lower voltage output is illustratively shown. The circuit includes of two cascaded inverters. The pull down NMOS transistors NH₁, NH₂ of both inverters are connected to a common ground. The pull-up transistor PH₁ of the input inverter is a high threshold voltage PMOS transistor connected to the higher voltage level V_{DD—HIGH}, and the pull-up transistor PH₂ of the output inverter is connected to the lower voltage level V_{DD—LOW}.

The above-described architecture does not provide equal delays and transition times for rising and falling edges. This is because the PMOS transistor of the output inverter requires the voltage at its gate to drop from V_{DD—HIGH} to (V_{DD—LOW}-V_{T—LOW}). Yet, the NMOS transistor requires its input voltage to rise from 0 to only V_{T—LOW}.

Simulation results for a 3.3V to 1.2V translation using the voltage translator of FIG. 1 are shown in FIG. 2. As may be seen, the rise and fall delays and transition times are unequal. Similarly, the simulation results for a 2.5V to 1.2V translation using the voltage translator of FIG. 1 are shown in FIG. 3. Once again, the rise and fall delays and transition times may be observed to be unequal.

U.S. Pat. No. 5,422,523 provides an example of a device for translating low voltages to high voltages. Even so, this method is generally unsuitable for converting from high voltages to low voltages.

Furthermore, U.S. Pat. No. 6,236,256 discloses a device for translating high voltages to low voltages. As shown in FIG. 4 thereof, the '256 patent describes a converter including an input sampler for sampling an input signal, a storage node for temporarily storing the sampled value, and precharge circuitry for precharging and discharging internal storage node capacitances. A latch is also included for retaining the sensed logic level, and an output low voltage inverter provides the output signal.

The invention described in the '256 patent does not provide equal rise and fall times for the output signal. In fact, the rise and fall times are likely to be significantly different. This is because the high-to-low transition of the output depends on the resistance of the SAMPLE switch and input signal rise-time, while the low-to-high transition depends only on the PRECHARGE value. This method is also relatively complex and expensive to implement.

### SUMMARY OF THE INVENTION

An object of the invention is to provide a device and method for providing voltage translation for signals from a circuit operating at a higher voltage level to a circuit operating at a lower voltage level.

Another object of the invention is to provide high-to-low voltage translation in a device having a relatively small device size.

A further object of the invention is to provide high-to-low voltage translation with equal rise and fall delays and equal rise and fall transition times.

These and other objects, features, and advantages of the invention are provided by a digital electronic circuit for providing high level to low level voltage translation with equal rise and fall delays and equal rise and fall transition times. In particular, the electronic circuit may include an input high voltage logic inverter operating at the high level voltage. The input high voltage logic inverter may be connected to an output low voltage logic inverter operating at the low voltage level through a voltage degradation circuit.

The voltage degradation circuit may include a plurality of series-connected transistors each biased to provide a fixed voltage drop. The voltage degradation circuit may provide a voltage that is greater than one threshold voltage below the low voltage level in the high state. This advantageously reduces output leakage current as well as the possibility of “crowbar” conduction. Further, the voltage degradation circuit may also provide a voltage that does not exceed a specified upper voltage rating of the low voltage transistors to reduce the possibility of transistor breakdown. An additional transistor may also be connected to feedback the output of the low level inverter to its input to further reduce output leakage current and the possibility of crowbar conduction.

A method aspect of the invention is for providing high level to low level voltage translation with equal rise and fall delays and equal rise and fall transition times. More particularly, the method may include providing an input inverter operating at the high voltage level and an output inverter operating at the low voltage level. Further, the output of the high voltage inverter may be coupled to the input of the low voltage inverter after reducing the output voltage of the high voltage inverter to the required level. The reduction of the voltage level may be performed by passing the voltage through a plurality of series-connected transistors, each of which is biased to provide a fixed voltage drop.

### BRIEF DESCRIPTION OF THE DRAWINGS

FIG. 1 is a schematic circuit diagram of a voltage converter in accordance with the prior art.

FIG. 2 is a simulated timing diagram of the prior art voltage converter of FIG. 1 for the case where V_{DD—HIGH}=3.3V and V_{DD—LOW}=1.2V (i.e., a voltage difference of 2.1V).

FIG. 3 is a simulated timing diagram of the prior art voltage converter of FIG. 1 for the case where V_{DD—HIGH}=2.5V and V_{DD—LOW}1.2V (i.e., a voltage difference of 1.3V).

FIG. 4 is a schematic circuit diagram of a first embodiment of the voltage converter in accordance with the present invention.

FIG. 5 is a simulated timing diagram for the voltage converter of FIG. 4 where V_{DD—HIGH}=3.3V and V_{DD—LOW}=1.2V (i.e., a voltage difference 2.1V).

FIG. 6 is a schematic circuit diagram of a second embodiment of the voltage converter in accordance with the present invention.

FIG. 7 is a simulated timing diagram for the voltage converter of FIG. 6 where V_{DD—HIGH}=2.5V and V_{DD—LOW}=1.2V (i.e., a voltage difference 1.3V).

FIG. 8 is a graph comparing the simulated timing diagrams of a prior art voltage converter and a voltage converter in accordance with the present invention where V_{DD—HIGH}=3.3V and V_{DD—LOW}=1.2V.

FIG. 9 is a graph comparing the simulated timing diagrams of a prior art voltage converter and a voltage converter in accordance with the present invention where V_{DD—HIGH}=2.5V and V_{DD—LOW}=1.2V.

FIG. 10 is a schematic circuit diagram of a third embodiment of the voltage converter in accordance with the present invention.

FIG. 11 is a schematic circuit diagram of a fourth embodiment of the voltage converter in accordance with the present invention.

### DETAILED DESCRIPTION OF THE PREFERRED EMBODIMENTS

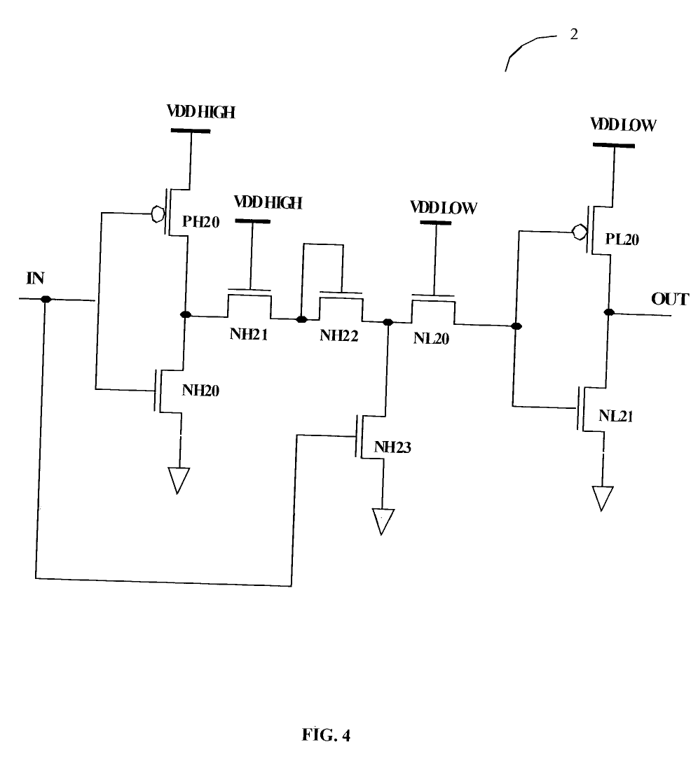

Turning now to FIG. 4, a first embodiment of the voltage translator or converter 2 in accordance with the invention is illustratively shown The voltage translator 2 includes a high voltage input inverter illustrativley including high threshold transistors PH20 and NH20. The first conduting end of transistor PH20 in the high voltage inverter is connected to the high voltage supply V_{DD—HIGH}. The second conducting end of transistor PH20 drives the first conducting end of the transistor NH20, which is also the output of the inverter. The second conducting end of the transistor NH20 is grounded.

The ouput of the high voltage inverter is connected to a series pass transistor NH21, the control terminal of which is raised to V_{DD—HIGH}. The other conducting terminal of the series pass transistor NH21 is connected to the shorted drain and gate of a second pass transistor NH22. The source of the transistor NH22 is connected to the drains of a low threshold voltage transistor NL20 and a high threshold voltage transistor NH23. The gate of the transistor NH23 is controlled by the input signal, while its source is grounded.

The gate of the transistor NL20 is connected to the lower supply voltage V_{DD—LOW}, while its source is connected to the input of a low voltage inverter including low threshold voltage transistors PL20 and NL21. The source terminals of the transistors PL20 and NL21 are connected to V_{DD—LOW} and ground, respectively. The drains of the transistors PL20 and NL21 are connected together to form the output terminal OUT.

The above-described cofiguration provides improved performance since the lower threshold transistors are connected to the lower supply voltages only, whereas the higher threshold transistors are supplied by the higher voltage only. Also, the higher voltages are brought down sufficiently before application to the lower threshold transistors, thus producing approximately equal rise and fall delays.

When the input is HIGH, the inverter formed by the transistors PH20 and NH20 outputs a LOW signal that tristates the transitor NH22. When the input is HIGH, the transistor NH23 turns ON and passes the LOW level to the drain of NL20, which passes it to the gates of the transistors PL20 and NL21. This causes the transistor NL21 to turn OFF while the transistor PL10 is turned ON, thus pulling the OUT terminal to V_{DD—LOW}. In this manner the HIGH input signal at V_{DD—HIGH} is converted to V_{DD—LOW}

Similarly, when the input is LOW, the transistor NH20 is turned OFF and the transistor PH20 is turned ON. This passes V_{DD—HIGH} to the drain of NH21. The transistor NH21 provides a threshold voltage drop (Vₜₕₙ) and passes a voltage of V_{DD—HIGH}−Vₜₕₙ to the gate and drain of the transistor NH22. This transistor introduces a second threshold voltage drop, bringing the input signal down to V_{DD—HIGH}−2Vₜₕₙ at the drain of the transistor NL20. Since the input is LOW, the transistor NH23 is OFF, allowing the transistor NL20 to pass the voltage V_{DD—LOW}−Vₜₗₙ to the gates of the transistors PL20 and NL21, where Vtln is the threshold voltage of low threshold NMOSs.

Normally, the threshold voltage of PMOS transistors is greater than that of NMOS transistors. Therefore, the transistor PL20 is OFF while the transistor NL21 is ON, thus bringing the output terminal to a LOW logic level. In this manner, the gate-to-source voltage (V_{gs}) and the gate-to-drain voltage (V_{gd}) of the lower threshold transistor are kept smaller than V_{DD—LOW}+Vₜₗₙ (i.e., by introducing the transistors NH21 and NH22). These transistors drop the high voltage V_{DD—HIGH} by 2Vₜₕₙ before appearing at the transistor NL20 to ensure the safety of the low threshold transistors. Since the PMOS transistors threshold voltages are usually greater than the NMOS transistors threshold voltage, no crowbar current flows in the circuit.

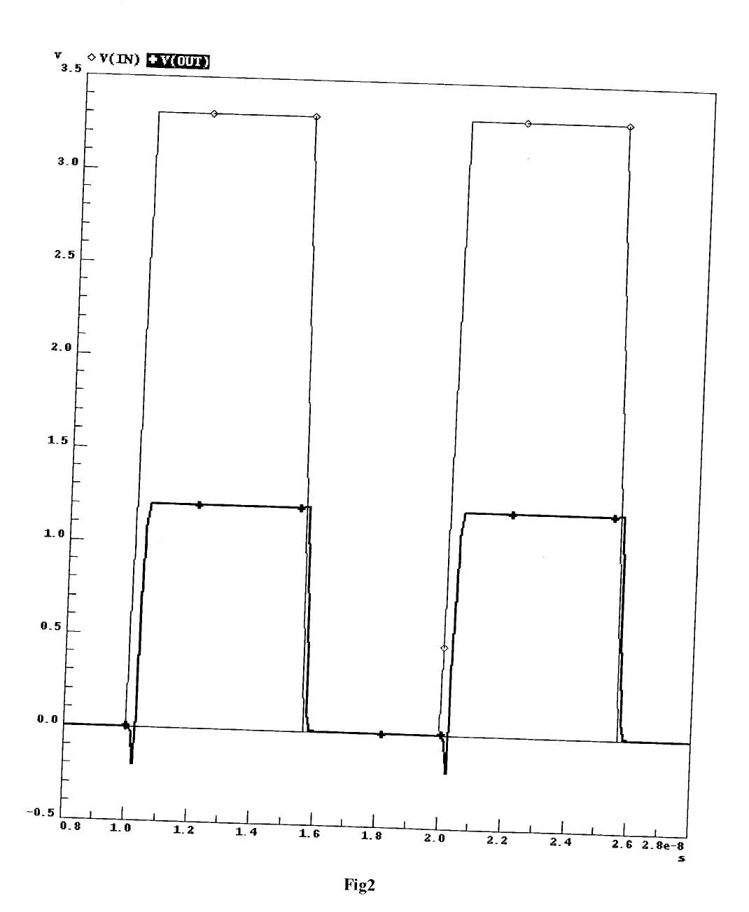

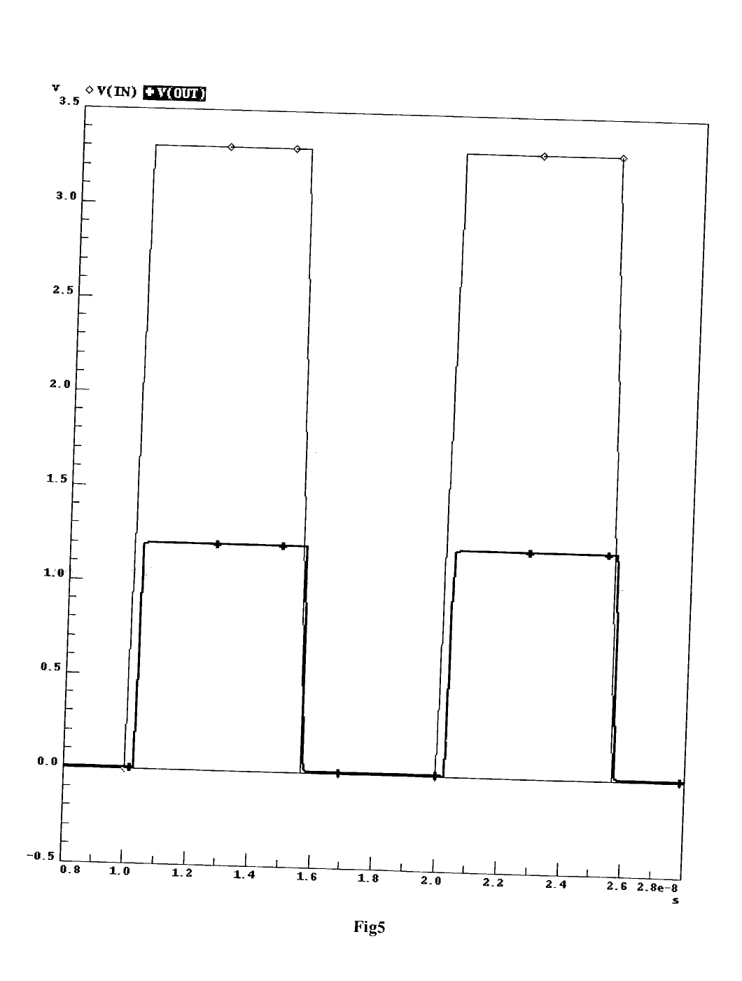

The simulated timing diagram for the voltage translator 2 for V_{DD—HIGH} of 3.3V and V_{DD—LOW} of 1.2V is illustrativley shown in FIG. 5. Upon comparing the timing diagram of FIG. 5 with that of FIG. 2 it will be seen that the device of the present invention produces better results than the prior art.

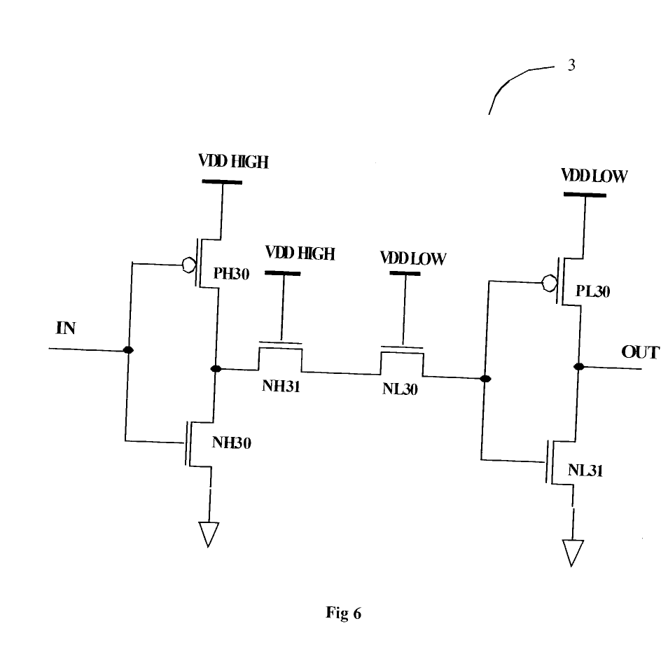

A second embodiment of a voltage translator 3 in accordance with the present invention for the case when V_{DD—HIGH} is 2.5V and V_{DD—LOW} is 1.2V is illustrated in FIG. 6. Here, pass transistors NH22 and NH23 are eliminated, as a single pass transistor NH31 is sufficient to protect the lower threshold transistor NL30. The remaining operation of the circuit is similar to that discussed above for the first embodiment of the invention.

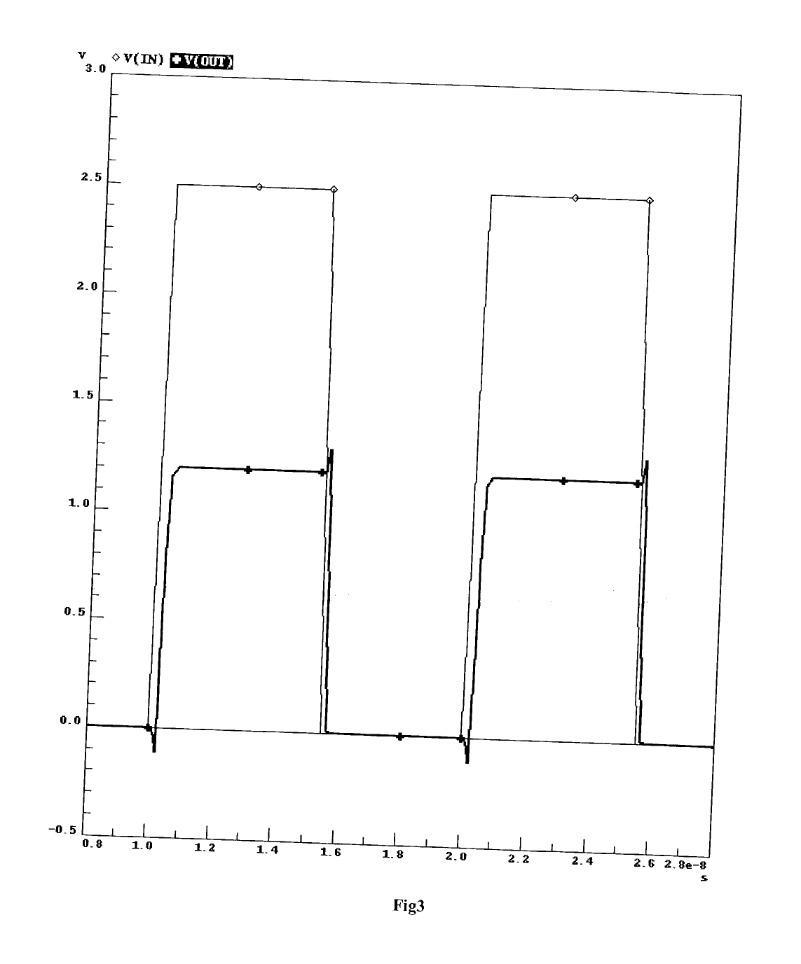

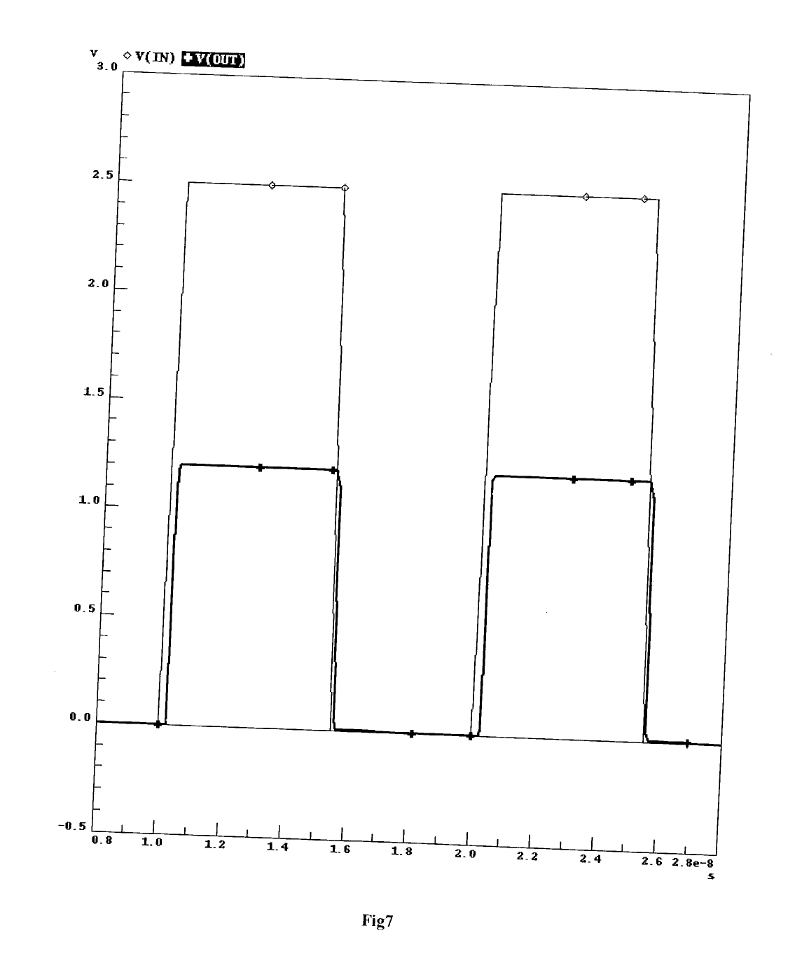

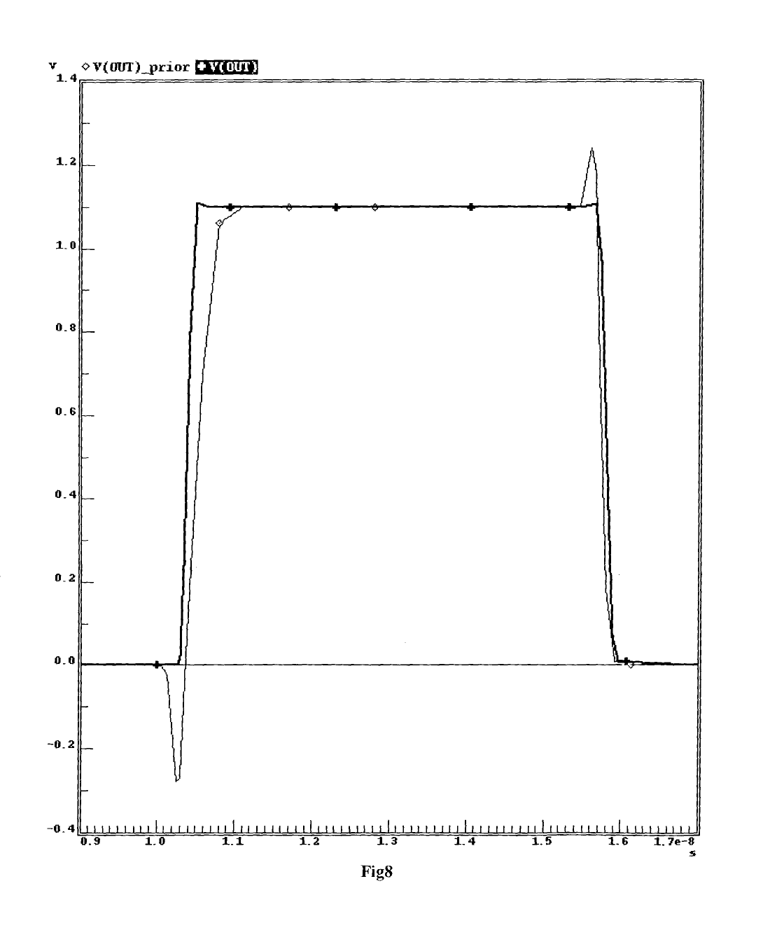

Referring to FIG. 7, the simulated timing diagram for the voltage translator 2 for the V_{DD—HIGH} of 2.5V and V_{DD—LOW} of 1.2V is shown. Again, comparing the timing diagrams of FIG. 8 and FIG. 3 shows that the circuit arrangement of the present invention produces shorter rise and fall delays and rise and fall transition times than the conventional voltage translator of the prior art.

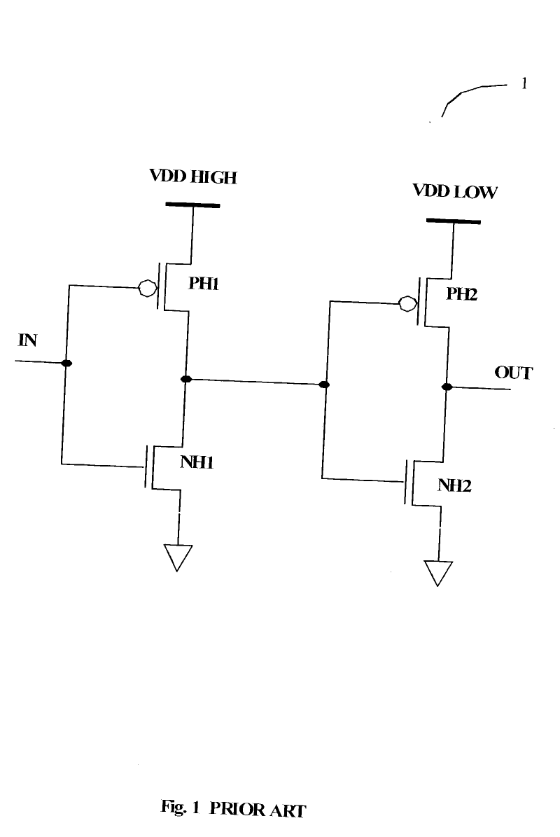

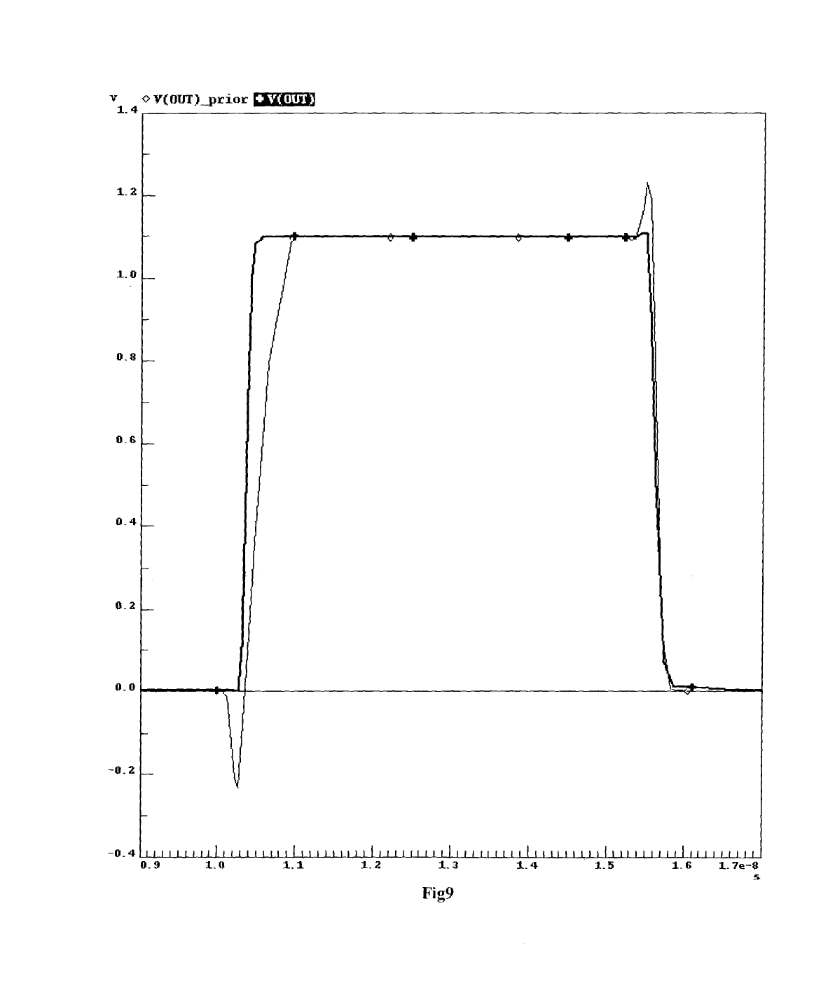

Simulation results for the operation of voltage converts in accordance with the present invention and the prior art where V_{DD—HIGH} is 3.3V and 2.5V and V_{DD—LOW} is 1.2V are illustrated in FIGS. 8 and 9, respectively. Here, VOUT is from the output OUT shown in the illustrated first and second embodiments of the present invention for V_{DD—HIGH} of 3.3V and 2.5V, respecttively, whereas V_{OUT—prior} is the output of the prior art voltage translator 1 of FIG. 1. The simulated results are for a worst-worst case, i.e., when temperature, supply voltage, and/or process parameters are at their worst or slowest. From the illustrated comparision it will be appreciated that the present invention returns better results than those of the prior art device.

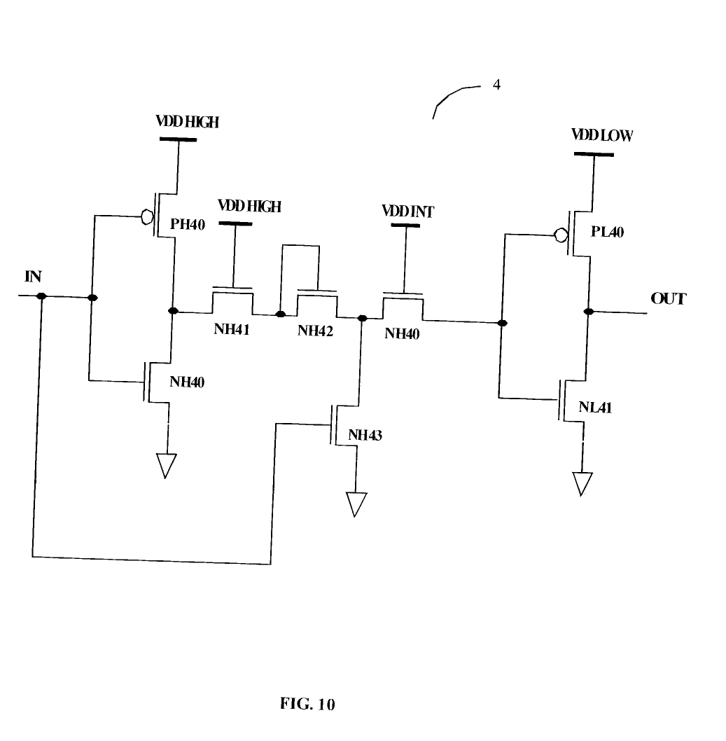

A third embodiment 4 of the invention is illustratively shown in FIG. 10. In this example, an intermediate voltage V_{DDINT} is introduced at the control terminal of a pass transitor NH40. For translating 3.3V to 1.2V, the intermidiate voltage V_{DDINT} is selected as 1.8V, whereas for a 5V to 2.5V conversion V_{DDINT} may be 3.3V, for example. The use of V_{DDINT} again reduces the likelihood of a crowbar current in the circuit.

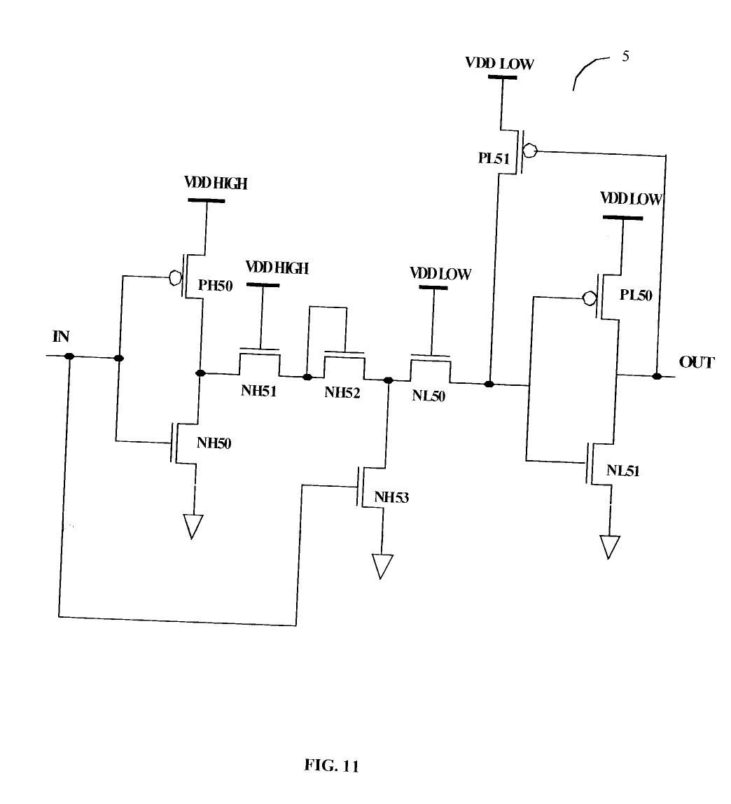

Referring to FIG. 11, a fourth voltage translator embodiement 5 in accordance with the invention is illustratively shown. In this embodiment, feedback is taken from the output through PL51 so that transistors PL50, PL51 and PL50 form a half latch. This half latch is used to restore the HIGH logic level and V_{DD—LOW} at the gates of the transistors PL50 and NL50. This approach again reduces the possibility of a crowbar current in the circuit.

It will be apparent to those skilled in the art that the foregoing embodiments are merely illustrative of the present invention, and are not intended to be exhaustive or limiting. These embodiments have been presented by way of example only, and various modifications may be made within the scope of the above invention. For instance, the number of series-connected transistors may be varied. Similarly, the intermediate voltage levels may be different from those described above. Such changes and modifications are understood to be included within the scope of the present invention as set forth in the following claims.

That which is claimed is:

1. A digital electronic circuit providing high level to low level voltage translation with equal rise and fall delays and equal rise and fall transition times, comprising:
an input high voltage logic inverter operating at the high level voltage;
an output low voltage logic inverter operating at the low voltage level; and
a voltage degradation means coupling the output of the high voltage inverter to the input of the low voltage inverter.

2. A digital electronic circuit as claimed in claim 1 wherein the voltage degradation means is a digital electronic circuit comprising a plurality of series-connected transistors each of which is biased to provide a fixed voltage drop.

3. A digital electronic circuit as claimed in claim 2 wherein the voltage degradation means provides a voltage that is not less than one threshold voltage below the low voltage level in the high state while ensuring that it never exceeds the maximum voltage rating of the low voltage transistors, so as to minimize output inverters leakage current and avoid the possibility of crowbar conduction or transistor breakdown.

4. A digital electronic circuit as claimed in claim 2 wherein the voltage degradation menas includes an additional transistor connected to feedback the output of the low level inverter to its input to minimize output leakage current and avoid the possibility of crowbar conduction.

5. A method for translating a high level voltage to a low level voltage while providing equal rise and fall delays and equal rise and fall transition times comprising the steps of:
providing a high voltage input inverter operating at the high level voltage;
providing at the low level voltage; and
coupling the output of the high voltage input inverter to the input of the low voltage output inverter after degrading it to the required level.

6. A method as claimed in claim 5 wherein the degrading of the voltage level from the output of the high voltage input inverter is performed by passing it through a plurality of transistors connected in series with each transistor being biased to provide a fixed voltage drug.

7. A method as claimed in claim 5 wherein the degraded voltage is adjusted to provide a voltage level that is greater than one threshold voltage below the low voltage level in the high state while ensuring that it never exceeds the maximum voltage rating of the low voltage transistors, so as to minimize output inverter leakage currect and avoid the possibility of crowbar conduction or transistor breakdown.

8. A method as claimed in claim 5 including providing feedback from the output of the output inverter to its input when the output is in the high state, so as to minimize output inverter leakage and avoid the possibility of crowbar conduction.
